(19) United States
(12) Patent Application Publication
(10) Pub. No.: US 2020/0303617 A1
(43) Pub. Date: Sep. 24, 2020

(54) CHARGE OUTPUT DEVICE, ASSEMBLY METHOD AND PIEZOELECTRIC ACCELERATION SENSOR

(71) Applicant: FATRI (Xiamen) Technologies Co., Ltd., Xiamen City (CN)

(72) Inventors: Yongzhong Nie, Xiamen City (CN); Chuan Nie, Xiamen City (CN)

(73) Assignee: FATRI (Xiamen) Technologies Co., Ltd., Xiamen City (CN)

(21) Appl. No.: 16/664,861

(22) Filed: Oct. 27, 2019

(30) Foreign Application Priority Data
Mar. 22, 2019 (CN) 201910223120.0

(51) Int. Cl. H01L 41/053; G01P 15/09; G01P 15/08; H01L 41/25

(52) U.S. Cl. CPC H01L 41/053; H01L 41/25; G01P 15/0802; G01P 15/09

(57) ABSTRACT

The present disclosure relates to a charge output device, an assembly method and a piezoelectric acceleration sensor. The charge output device includes a base, including a polygonal connecting member including a plurality of sides; a piezoelectric assembly, including at least two piezoelectric units distributed along a circumferential direction of the connecting member and spaced apart from each other, the at least two piezoelectric units are disposed corresponding to at least two of the plurality of sides of the connecting member, and each piezoelectric unit includes at least one piezoelectric crystal, wherein the respective piezoelectric crystals of the at least two piezoelectric units are connected in parallel; and a mass assembly, disposed on an outer circumferential side of the piezoelectric assembly such that the piezoelectric assembly is located between the connecting member and the mass assembly, the connecting member, the piezoelectric assembly and the mass assembly are interference-fitted with each other.

### CROSS REFERENCE TO RELATED APPLICATION

This application claims priority to Chinese Patent Application No. 201910223120.0, filed on Mar. 22, 2019, which is hereby incorporated by reference in its entirety.

### TECHNICAL FIELD

The present disclosure relates to a technical field of sensor technologies, and particularly relates to a charge output device, an assembly method and a piezoelectric acceleration sensor.

### BACKGROUND

A piezoelectric acceleration sensor, also known as a piezoelectric accelerometer, is an inertial sensor. The principle of the piezoelectric acceleration sensor lies in the piezoelectric effect of a piezoelectric element. When the accelerometer is vibrated, a force applied on the piezoelectric element by a mass changes. When a vibration frequency under measurement is much lower than an inherent frequency of the accelerometer, the change of the force is proportional to an acceleration under detection. A standard piezoelectric acceleration sensor is used to calibrate the acceleration sensor. Therefore, the requirements on performance of the standard piezoelectric acceleration sensor is much higher, for example, a higher sensitivity is required. However, the existing piezoelectric acceleration sensor is generally not sensitive enough to meet the requirements of the standard piezoelectric acceleration sensor.

Therefore, there is a dire need for a charge output device with higher sensitivity to meet the requirements of the standard piezoelectric acceleration sensor.

### SUMMARY

Embodiments of the present disclosure provide a charge output device, an assembly method thereof, and a piezoelectric acceleration sensor, which can improve sensitivity of the charge output device.

On one aspect, the present disclosure discloses a charge output device, includes a base, including a polygonal connecting member including a plurality of sides; a piezoelectric assembly, including at least two piezoelectric units distributed along a circumferential direction of the connecting member and spaced apart from each other, the at least two piezoelectric units are disposed corresponding to at least two of the plurality of sides of the connecting member, and each piezoelectric unit includes at least one piezoelectric crystal, wherein the respective piezoelectric crystals of the at least two piezoelectric units are connected in parallel; and a mass assembly, disposed on an outer circumferential side of the piezoelectric assembly such that the piezoelectric assembly is located between the connecting member and the mass assembly, wherein the connecting member, the piezoelectric assembly and the mass assembly are interference-fitted with each other.

According to one aspect of the present disclosure, each piezoelectric crystal is formed as a bent sheet-like member, a shape of which matches a shape of the side of the connecting member; or each piezoelectric crystal is formed as a straight sheet-like member, a shape of which matches a shape of the side of the connecting member, and on each side of the connecting member, one piezoelectric unit is disposed correspondingly.

According to one aspect of the present disclosure, each of two surfaces of each piezoelectric crystal opposite to each other in a normal direction of a circumferential surface of the connecting member is provided with a conductive film, and each piezoelectric unit includes two or more piezoelectric crystals stacked in the normal direction, wherein two surfaces of two adjacent piezoelectric crystals adjacent to each other have the same polarity.

According to one aspect of the present disclosure, the charge output device further includes a plurality of electrode plates, the plurality of electrode plates and the piezoelectric crystals of respective layers are alternately stacked in the normal direction, and the number of layers of the plurality of electrode plates is one more than the number of layers of the piezoelectric crystals, wherein each electrode plate includes a fitting portion and a connecting portion, the fitting portion is disposed corresponding to the piezoelectric crystal, and the connecting portion is electrically connected to the fitting portion so that each electrode plate is formed as an annular member that is discontinuous in a circumferential direction; and wherein the respective electrode plates of odd-numbered layers are electrically connected by a wire segment, and the respective electrode plates of even-numbered layers are electrically connected by another wire segment, so that the respective piezoelectric crystals of the at least two piezoelectric units are connected in parallel.

According to one aspect of the present disclosure, the fitting portion has a size greater than or equal to that of the piezoelectric crystal, so that the piezoelectric crystal can completely fit to the fitting portion; and/or the connecting portion has a width in an axial direction of the connecting member smaller than that of the fitting portion.

According to one aspect of the present disclosure, the wire segment electrically connects the electrode plates of the respective odd-numbered layers in the circumferential direction at discontinuous positions of the electrode plates; and the another wire segment electrically connects the electrode plates of the respective even-numbered layers in the circumferential direction at discontinuous positions of the electrode plates.

According to one aspect of the present disclosure, the mass assembly includes a plurality of masses distributed along the circumferential direction and spaced apart from each other, and on an outer circumferential side of each piezoelectric unit, at least one mass is disposed correspondingly.

According to one aspect of the present disclosure, the charge output device further includes a heat shrink ring, disposed surrounding the mass assembly and interference-fitted with the mass assembly; and an insulating plate, disposed surrounding the connecting member and located between the connecting member and each piezoelectric unit.

On a second aspect, the present disclosure discloses an assembly method of a charge output device, including steps of: performing a heat treatment on a base to eliminate processing stress in the base, wherein the base includes a polygonal connecting member including a plurality of sides; disposing at least two piezoelectric units spaced apart from each other along a circumferential side of the connecting member, wherein the at least two piezoelectric units are disposed corresponding to at least two sides of the plurality of sides of the connecting member, and each piezoelectric unit includes at least one piezoelectric crystal; connecting the respective piezoelectric crystals of the at least two piezoelectric units in parallel by electrode plates; disposing a mass assembly on an outer circumferential side of the at least two piezoelectric units; and disposing a heat shrink ring to surround the mass assembly on an outer side of the mass assembly and heating the heat shrink ring to shrink it, so that the heat shrink ring, the mass assembly, the at least two piezoelectric units and the connecting member are interference-fitted with each other.

On a third aspect, the present disclosure discloses a piezoelectric acceleration sensor, including: a charge output device according to any of the above embodiments; a case, surrounding the charge output device and disposed on the base; and a signal output element, electrically connected to the piezoelectric assembly.

### BRIEF DESCRIPTION OF THE DRAWINGS

In order to illustrate the technical solutions of the embodiments of the present disclosure more clearly, the drawings to be used in the embodiments of the present disclosure will be briefly described below. It is obvious that the drawings described below are only some embodiments of the present disclosure, and the person skilled in the art can obtain other drawings based on these drawings without paying any creative work.

FIG. 1 is a schematic top view showing a configuration of a charge output device according to an embodiment of the present disclosure;

FIG. 2 is a schematic cross-sectional view showing a configuration of a charge output device according to an embodiment of the present disclosure;

FIG. 3 is a schematic top view showing a configuration of a charge output device according to another embodiment of the present disclosure;

FIG. 4 is a schematic view showing a configuration of an electrode plate according to an embodiment of the present disclosure;

FIG. 5 is a schematic view showing electrical connection of electrode plates of odd-numbered layers or even-numbered layers according to an embodiment of the present disclosure;

FIG. 6 is a flow chart showing an assembly method of a charge output device according to an embodiment of the present disclosure; and

FIG. 7 is a cross-sectional view showing a configuration of a piezoelectric acceleration sensor according to an embodiment of the present disclosure.

### DETAILED DESCRIPTION

Features and exemplary embodiments of various aspects of the present disclosure will be described in detail below. In the following detailed description, numerous specific details are set forth to provide a full understanding of the present disclosure. However, it shall be apparent to the person skilled in the art that the present disclosure may be implemented without some of the details. The following description of the embodiments is made merely to provide a better understanding of the present disclosure by showing examples of the present disclosure. In the drawings and the following description, at least some of well-known structures and techniques are not shown to avoid unnecessarily obscuring the present disclosure. Further, for clarity, size of part of the structure may be exaggerated. Furthermore, features, structures, or characteristics described hereinafter may be combined in any suitable manner into one or more embodiments.

Orientations in the following description refer to directions as shown in the drawings, and are not intended to define specific structure of the embodiments of the present disclosure. In the description of the present disclosure, it shall be noted that, unless otherwise clearly stated and defined, the terms such as “installation”, “connection” shall be understood broadly, and may be, for example, a fixed connection, a disassemble connection, or an integral connection, and may be a direct connection or an indirect connection through an intermediate medium. The specific meaning of the above terms in the present disclosure can be understood by the person skilled in the art according to actual circumstance.

It should be noted that, the embodiments in the present application and the features in the embodiments may be combined with each other when there is no conflict. The embodiments will be described in detail below with reference to the accompanying drawings.

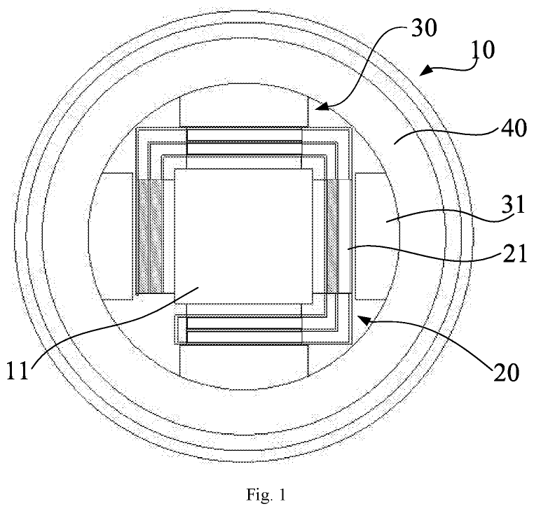

For a better understanding of the present disclosure, a charge output device, an assembly method, and a piezoelectric acceleration sensor of the present disclosure will be described in detail below with reference to FIGS. 1 to 7.

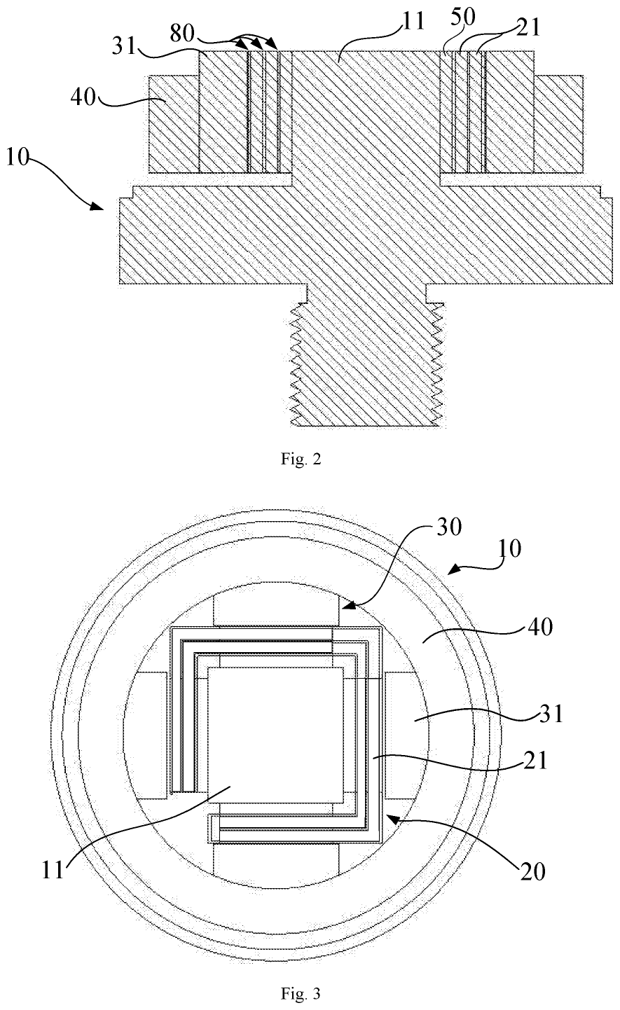

Referring to FIG. 1 and FIG. 2 together, wherein FIG. 1 is a schematic top view of a configuration of a charge output device according to an embodiment of the present disclosure, and FIG. 2 is a cross-sectional view of a configuration of a charge output device according to an embodiment of the present disclosure. The charge output device of the present embodiment includes a base 10, a piezoelectric assembly and a mass assembly 30. The base 10 includes a polygonal connecting member 11, which includes a plurality of sides. For convenience of processing and assembly, the connecting member 11 may have a cross section perpendicular to an axial direction of the connecting member 11 in a shape of a regular polygon, that is, the plurality of sides of the connecting member 11 have the same shape. The piezoelectric assembly includes at least two piezoelectric units 20 distributed along a circumferential direction of the connecting member 11 and spaced apart from each other, and the at least two piezoelectric units 20 are disposed corresponding to at least two sides of the plurality of sides of the connecting member 11. Each piezoelectric unit 20 includes at least one piezoelectric crystal 21, and the piezoelectric crystals 21 are connected in parallel. The mass assembly 30 is disposed on an outer circumferential side of the piezoelectric assembly, such that the piezoelectric assembly is located between the connecting member 11 and the mass assembly 30. In the above configuration, the connecting member 11, the piezoelectric assembly and the mass assembly 30 are interference-fitted with each other to ensure an overall rigidity of the charge output device.

In the present embodiment, the connecting member 11 includes a plurality of sides, for facilitating the arrangement of the piezoelectric unit 20 including at least one piezoelectric crystal 21 on a circumferential side of each side of the connecting member 11. As a result, the number of the piezoelectric crystals 21 on a circumferential side of the connecting member 11 can be increased, and space can be saved. Further, by connecting the respective piezoelectric crystals 21 in parallel, a sensitivity of the charge output device can be improved, thereby improving a sensitivity of the piezoelectric acceleration sensor. Further, the connecting member 11, the piezoelectric assembly and the mass assembly 30 are interference-fitted with each other, and are rigidly contact with each other without need of adhesive layers. Thus, the overall rigid of the charge output device can be increased, and thus frequency response characteristics and resonance characteristics of the piezoelectric acceleration sensor can be improved.

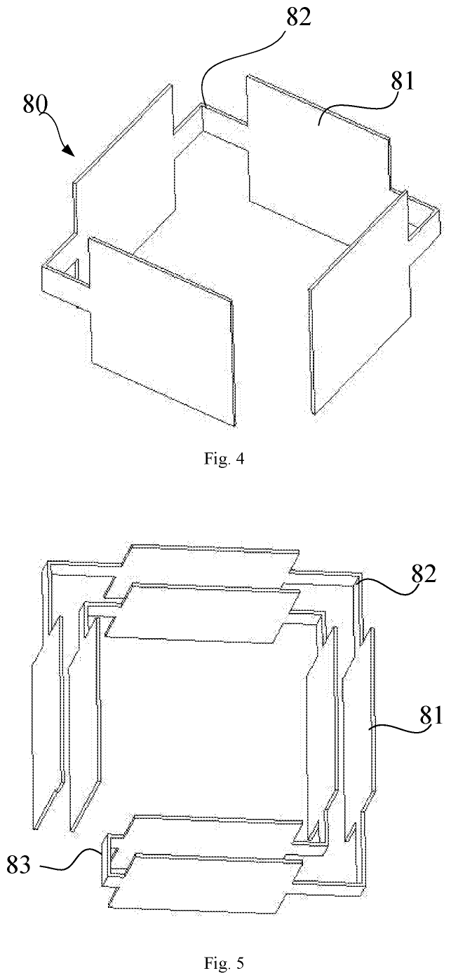

In some alternative embodiments, please refer to FIG. 3. FIG. 3 is a schematic top view of a configuration of a charge output device according to another embodiment of the present disclosure. The piezoelectric crystal 21 of the charge output device in the present embodiment is formed as a bent sheet-like member, a shape of which matches a shape of the side of the connecting member 11. The specific number of bent portions of the bent sheet-like member is not limited in the present disclosure, as long as the shape formed by the bending can match the side of the connecting member 11. In the drawings, as an example, the bent sheet-like member has one bent portion, the connecting member 11 includes four sides, and each bent sheet-like member is correspondingly disposed on two sides of the connecting member 11. It should be understood that the piezoelectric crystals 21 are symmetrically disposed on the circumferential side of the connecting member 11 in order for a better charge output.

In some other alternative embodiments, referring to FIG. 1, the piezoelectric crystal 21 may be formed as a straight sheet-like member, a shape of which matches a shape of the side of the connecting member 11, and each side of the connecting member 11 is correspondingly provided with one piezoelectric unit 20. Since the piezoelectric crystal 21 is formed as a straight sheet-like member, it is convenient for the piezoelectric crystal 21 in such shape to be disposed on each side of the connecting member 11, and further stacking multiple piezoelectric crystals 21 on each side. By connecting the respective piezoelectric crystals in parallel, the sensitivity of the charge output device can be effectively increased. Moreover, the straight sheet-like piezoelectric crystal 21 has a simple structure, is easy to process, and is easy to stack.

In some alternative embodiments, each piezoelectric crystal 21 is provided with a conductive film on each of two surfaces opposite to each other in a normal direction of a circumferential surface of the connecting member 11, to facilitate electrical connection of the respective piezoelectric crystals 21. Further, the piezoelectric unit 20 includes two or more piezoelectric crystals 21 stacked in the normal direction, and two surfaces of adjacent two piezoelectric crystals 21 adjacent to each other have the same polarity, to facilitate the parallel connection of the respective piezoelectric crystals 21. The piezoelectric crystal 21 of the present embodiment may be made of a quartz single crystal. The quartz single crystal has good thermal stability and temperature drift characteristics, and has high sensitivity, excellent linearity, and high dielectric constant. Moreover, a connection of a plurality of quartz single crystals in parallel can increase the sensitivity of the charge output device and improve an anti-interference ability of the charge output device. The conductive film provided on each of the two surfaces of the piezoelectric crystal 21 opposite to each other may be a gold plating film. It should be understood that the polarities of the two surfaces opposite to each other and provided with the conductive films are different, after polarization of the piezoelectric crystal 21.

In some alternative embodiments, the charge output device further includes a plurality of electrode plates 80. The plurality of electrode plates 80 and the piezoelectric crystals 21 of respective layers are stacked alternately in the normal direction of the circumferential surface of the connecting member 11, and the number of layers of the electrode plates 80 is one more than the number of layers of the piezoelectric crystals 21. Referring to FIG. 4, wherein FIG. 4 is a schematic view of a configuration of an electrode plate according to an embodiment of the present disclosure. The electrode plate 80 of the present embodiment includes a fitting portion 81 and a connecting portion 82. The fitting portion 81 is disposed corresponding to the piezoelectric crystal 21. The connecting portion 82 is electrically connected to the fitting portion 81, such that each electrode plate 80 is formed into an annular member that is discontinuous in a circumferential direction. It can be understood that the annular member of the present embodiment is formed as a polygonal annular member, which includes three, four or five sides. The number of sides of the annular member is not limited in the present disclosure, but is consistent with the number of the sides of the connecting member 11. In the present embodiment, the annular members of odd-numbered layers are electrically connected by a wire segment 83, and the annular members of even-numbered layers are electrically connected by another wire segment 83, thereby achieving parallel connection of the respective piezoelectric crystals 21. In the present embodiment, regarding the odd-numbered layers and the even-numbered layers, a layer of the piezoelectric crystal 21 closest to the connecting member 11 may be a first layer, and layers arranged sequentially outwardly are a second layer, a third layer, etc.; or, a layer of the piezoelectric crystal 21 farthest away from the connecting member 11 is a first layer, and layers arranged sequentially inwardly are a second layer, a third layer, etc. In the present disclosure, a connection position of the wire segment 83 is not limited. However, in order to reduce a height of the charge output device, preferably, the wire segment 83 is disposed at a discontinuous position in the circumferential direction of the electrode plates 80, to electrically connect the electrode plates 80 of the odd-numbered layers or the even-numbered layers in the circumferential direction as shown in FIG. 5, wherein FIG. 5 is a schematic view of an electrical connection of odd-numbered or even-numbered layers of electrode plates according to an embodiment of the present disclosure. Each of the fitting portion 81, the connecting portion 82, and the wire segment 83 of the present embodiment may be made of at least one of pure nickel and a nickel-chromium alloy.

As an example, the connecting member 11 has a square cross section perpendicular to the axial direction and includes four sides, and two layers of the piezoelectric crystals 21 formed as a straight sheet-like member are disposed on each side. In this case, three layers of electrode plates 80 are disposed on the circumferential side of the connecting member 11. As shown in FIGS. 1 and 5, by taking the connecting member 11 as a center and counting from inside to outside, a first layer of the electrode plates 80 and a third layer of the electrode plates 80 are discontinuous at the same position on the circumferential side of the connecting member 11, and are connected at ends on the same side in the circumferential direction by the wire segment 83, so that the first layer of the electrode plates 80 and the third layer of the electrode plates 80 are connected to form an integral member with two free ends.

Further, in order to ensure a good fit of the piezoelectric crystal 21 and the electrode plate 80, the fitting portion 81 of the electrode plate 80 has a size greater than or equal to that of the piezoelectric crystal 21. Alternatively, the size of the fitting portion 81 is the same as the size of the piezoelectric crystal 21, and the fitting portion 81 and the piezoelectric crystal 21 fit to each other completely, to avoid interference of signals between the fitting portions 81 of adjacent layers. The connecting portion 82 of the electrode plate 80 has a width in the axial direction of the connecting member 11 smaller than that of the fitting portion 81 of the electrode plate 80, to reduce an electric resistance of the entire electrode plate 80.

In some alternative embodiments, the mass assembly 30 includes a plurality of masses 31 spaced apart from each other in a circumferential direction, and at least one mass 31 is disposed correspondingly on an outer circumferential side of each piezoelectric unit 20. The respective masses 31 are disposed on an outer circumferential side of the outermost electrode plate 80. The masses 31 are fitted to the outermost electrode plate 80 and are interference-fitted with the electrode plate 80. The respective masses 31 are disposed on the outer circumferential side of the electrode plate 80, that is, the entire mass assembly 30 is discontinuous in a circumferential direction, which facilitates to adjust positions of the respective masses 31 to realize the interference fit between the respective masses 31 and the electrode plate 80. The mass assembly 30 of the present embodiment may be made of 316L stainless steel, and has strong corrosion resistance and heat resistance.

In some alternative embodiments, the charge output device further includes a heat shrink ring 40 that is disposed surrounding the mass assembly 30 and interference-fitted with the mass assembly 30. The heat shrink ring 40 may be made of a nickel-titanium memory alloy, which is treated by cold expansion and is heat shrinkable. The heat shrink ring 40 of the present embodiment can increase a preload force on the circumferential side of the mass assembly 30 such that the connecting member 11, the piezoelectric assembly and the mass assembly 30 are interference-fitted with each other, thereby enhancing the overall rigidity of the charge output device.

Further, the charge output device of the present embodiment further includes an insulating plate 50, which is disposed surrounding the connecting member 11 and located between the connecting member 11 and the piezoelectric units 20. The arrangement of the insulating plate 50 can prevent an electric charge of the piezoelectric assembly from moving to the connecting member 11, thereby improving a measurement accuracy of the piezoelectric acceleration sensor. The insulating plate 50 may be made of 95 alumina ceramic and has good insulating property. The specific shape of the insulating plate 50 is not limited in the present disclosure, as long as the insulation between the electrode plate 80 of the piezoelectric assembly and the connecting member 11 can be achieved. For example, the insulating plate 50 may be formed as an annular member, and is disposed surrounding the connecting member 11 and located between the connecting member 11 and the piezoelectric assembly. Further, the insulating sheet 50 may be formed as a sheet-like member, and on each side of the connecting member 11, one insulating plate 50 is disposed correspondingly and is located between the connecting member 11 and the innermost electrode plate 80.

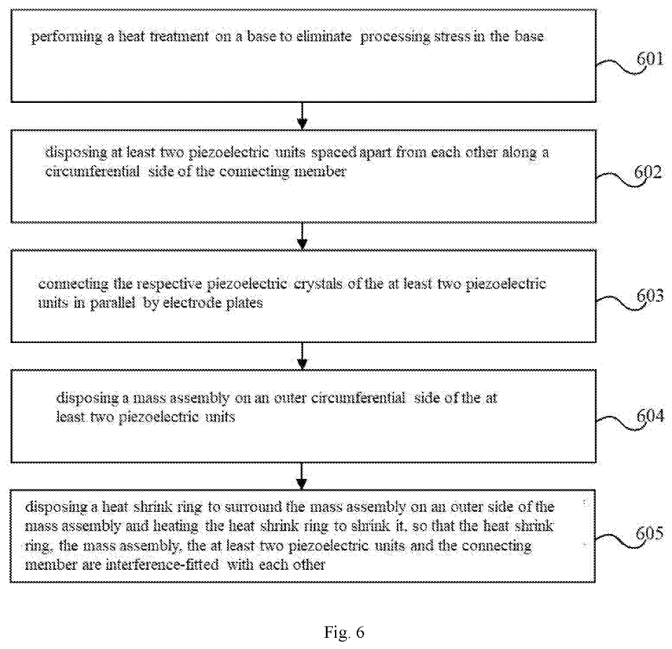

The present disclosure further provides an assembly method for a charge output device. Please refer to FIG. 6. FIG. 6 is a flow chart of an assembly method for a charge output device according to an embodiment of the present disclosure. The assembly method of the present embodiment includes the steps as below.

In step 601, a heat treatment is performed on a base to eliminate processing stress in the base.

The base 10 in this step includes a polygonal connecting member 11 including a plurality of sides. The material of the base 10 is selected from α+β titanium alloy, with a density from 3 g/cm⁻³ to 5 g/cm⁻³ and an elastic modulus from 1.0×10⁵ MPa to 1.2×10⁵ MPa, which has a high strength-to-weight ratio. Specifically, α+β titanium alloy of TC4 type can be used. The heat treatment of the formed base 10 can eliminate the processing stress in the base 10, stabilize a size of the base 10, increase a strength of the base 10, and remove harmful elements (for example, hydrogen) added to the base 10 during processing. The specific heat treatment may include one or more of annealing, solution treatment, and failure treatment. The heat treatment of the present embodiment is performed under vacuum.

In step 602, at least two piezoelectric units are disposed along a circumferential side of the connecting member and spaced apart from each other.

In this step, at least two piezoelectric units 20 are disposed corresponding to at least two of the plurality of sides of the connecting member 11, and each piezoelectric unit 20 includes at least one piezoelectric crystal 21.

In step 603, the respective piezoelectric crystals are connected in parallel through electrode plates.

In this step, the respective piezoelectric crystals 21 are connected in parallel via electrode plates 80, which can improve a sensitivity of the charge output device.

In step 604, a mass assembly is disposed on an outer circumferential side of the piezoelectric units.

In step 605, a heat shrink ring is disposed surrounding an outer side of the mass assembly and is heated to shrink, so that the heat shrink ring, the mass assembly, the piezoelectric units and the connecting member are interference-fitted with each other.

In this step, by heating the heat shrink ring 40 to shrink, a preloading force on a circumferential side of the mass assembly is increased, thereby achieving an interference fit between the mass assembly 30, the piezoelectric units 20, the electrode plates 80 and the connecting member 11.

In the present embodiment, the heat treatment is performed on the formed base 10 to eliminate processing stress in the base 10, which can stabilize the size of the base 10, increase the strength of the base 10, and remove the harmful elements (for example, hydrogen) added to the base 10 during processing. The connecting member 11 includes a plurality of sides, and at least two sides are provided with the piezoelectric unit 20, which includes at least one piezoelectric crystal 21. Thus, the number of the piezoelectric crystals 21 can be increased and space can be saved. By connecting the piezoelectric crystals 21 in parallel through the electrode plates 80, the sensitivity of the charge output device can be improved. Further, by increasing a radial preloading force by use of the heat shrink ring 40, the interference fit between the mass assembly 30, the piezoelectric units 20 and the connecting member 11 can be achieved, which can increase the overall rigidity of the charge output device, thereby improving the frequency response characteristics and resonance characteristics of the piezoelectric acceleration sensor.

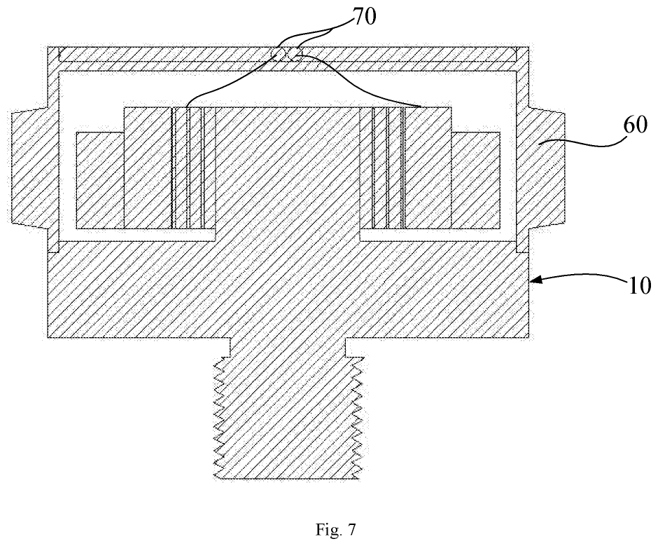

The present disclosure further provides a piezoelectric acceleration sensor. Please refer to FIG. 7 together, wherein FIG. 7 is a cross-sectional view of a configuration of a piezoelectric acceleration sensor according to an embodiment of the present disclosure. The piezoelectric acceleration sensor of the present embodiment includes the charge output device according to the above embodiments, a case 60, and a signal output element 70. The case 60 is disposed surrounding the charge output device and is disposed on the base 10, which can seal and protect the charge output device. The signal output element 70 is electrically connected to the mass assembly 30 and the piezoelectric assembly. Specifically, the signal output element 70 can be electrically connected to the mass assembly 30 and the piezoelectric assembly through two signal transmission lines. One end of one signal line is connected to the mass assembly 30, while the other end of the one signal line is connected to the signal output element 70. Moreover, one end of the other signal line is connected to the electrode plate 80 that is not in electrical contact with the mass assembly 30, and the other end of the other signal line is connected to the signal output element 70. Thereby, a signal of the charge output device can be transmitted to an external device through the signal output element 70. The same heat treatment as the base 10 may be performed on the case 60 of the piezoelectric acceleration sensor of the present embodiment, to eliminate the processing stress in the case 60, stabilize a size of the case 60, increase a strength of the case 60, and remove harmful elements added to the case 60 during the forming process. Thereby, the overall rigidity of the piezoelectric acceleration sensor can be increased.

The piezoelectric acceleration sensor according to the embodiment of the present disclosure includes the charge output device of the above embodiment, and thus has the advantageous effects of the charge output device of the above embodiment, which will not be described herein any longer.

The above description is only the specific embodiment of the present disclosure, and the scope of the present disclosure is not limited thereto. The person skilled in the art can easily think of various equivalent modifications or substitutions within the technical scope disclosed by the present disclosure, which also fall within the protective scope of the present disclosure. Therefore, the protective scope of the present disclosure is determined by the scope of the claims.

What is claimed is:

1. A charge output device, comprising:
a base, comprising a polygonal connecting member comprising a plurality of sides;
a piezoelectric assembly, comprising at least two piezoelectric units distributed along a circumferential direction of the connecting member and spaced apart from each other, the at least two piezoelectric units are disposed corresponding to at least two of the plurality of sides of the connecting member, and each piezoelectric unit comprises at least one piezoelectric crystal, wherein the respective piezoelectric crystals of the at least two piezoelectric units are connected in parallel; and
a mass assembly, disposed on an outer circumferential side of the piezoelectric assembly such that the piezoelectric assembly is located between the connecting member and the mass assembly,
wherein the connecting member, the piezoelectric assembly and the mass assembly are interference-fitted with each other.

2. The charge output device according to claim 1, wherein each piezoelectric crystal is formed as a bent sheet-like member, a shape of which matches a shape of the side of the connecting member.

3. The charge output device according to claim 1, wherein each piezoelectric crystal is formed as a straight sheet-like member, a shape of which matches a shape of the side of the connecting member, and on each side of the connecting member, one piezoelectric unit is disposed correspondingly.

4. The charge output device according to claim 1, wherein each of two surfaces of each piezoelectric crystal opposite to each other in a normal direction of a circumferential surface of the connecting member is provided with a conductive film, and each piezoelectric unit comprises two or more piezoelectric crystals stacked in the normal direction, wherein two surfaces of two adjacent piezoelectric crystals adjacent to each other have the same polarity.

5. The charge output device according to claim 4, further comprising:
a plurality of electrode plates, the plurality of electrode plates and the piezoelectric crystals of respective layers are alternately stacked in the normal direction, and the number of layers of the plurality of electrode plates is one more than the number of layers of the piezoelectric crystals, wherein each electrode plate comprises a fitting portion and a connecting portion, the fitting portion is disposed corresponding to the piezoelectric crystal, and the connecting portion is electrically connected to the fitting portion so that each electrode plate is formed as an annular member that is discontinuous in a circumferential direction; and
wherein the respective electrode plates of odd-numbered layers are electrically connected by a wire segment, and the respective electrode plates of even-numbered layers are electrically connected by another wire segment, so that the respective piezoelectric crystals of the at least two piezoelectric units are connected in parallel.

6. The charge output device according to claim 5, wherein the fitting portion has a size greater than or equal to that of the piezoelectric crystal, so that the piezoelectric crystal can completely fit to the fitting portion.

7. The charge output device according to claim 5, wherein the connecting portion has a width in an axial direction of the connecting member smaller than that of the fitting portion.

8. The charge output device according to claim 6, wherein the connecting portion has a width in an axial direction of the connecting member smaller than that of the fitting portion.

9. The charge output device according to claim 5, wherein the wire segment electrically connects the electrode plates of the respective odd-numbered layers in the circumferential direction at discontinuous positions of the electrode plates; and the another wire segment electrically connects the electrode plates of the respective even-numbered layers in the circumferential direction at discontinuous positions of the electrode plates.

10. The charge output device according to claim 1, wherein the mass assembly comprises a plurality of masses distributed along the circumferential direction and spaced apart from each other, and on an outer circumferential side of each piezoelectric unit, at least one mass is disposed correspondingly.

11. The charge output device according to claim 1, further comprising:
a heat shrink ring, disposed surrounding the mass assembly and interference-fitted with the mass assembly; and
an insulating plate, disposed surrounding the connecting member and located between the connecting member and each piezoelectric unit.

12. An assembly method of a charge output device, comprising steps of:
performing a heat treatment on a base to eliminate processing stress in the base, wherein the base comprises a polygonal connecting member comprising a plurality of sides;
disposing at least two piezoelectric units spaced apart from each other along a circumferential side of the connecting member, wherein the at least two piezoelectric units are disposed corresponding to at least two sides of the plurality of sides of the connecting member, and each piezoelectric unit comprises at least one piezoelectric crystal;
connecting the respective piezoelectric crystals of the at least two piezoelectric units in parallel by electrode plates;
disposing a mass assembly on an outer circumferential side of the at least two piezoelectric units; and
disposing a heat shrink ring to surround the mass assembly on an outer side of the mass assembly and heating the heat shrink ring to shrink it, so that the heat shrink ring, the mass assembly, the at least two piezoelectric units and the connecting member are interference-fitted with each other.

13. A piezoelectric acceleration sensor, comprising:
a charge output device according to claim 1;
a case, surrounding the charge output device and disposed on the base; and
a signal output element, electrically connected to the piezoelectric assembly.

14. The piezoelectric acceleration sensor according to claim 13, wherein each piezoelectric crystal is formed as a bent sheet-like member, a shape of which matches a shape of the side of the connecting member.

15. The piezoelectric acceleration sensor according to claim 13, wherein each piezoelectric crystal is formed as a straight sheet-like member, a shape of which matches a shape of the side of the connecting member, and on each side of the connecting member, one piezoelectric unit is disposed correspondingly.

16. The piezoelectric acceleration sensor according to claim 13, wherein each of two surfaces of each piezoelectric crystal opposite to each other in a normal direction of a circumferential surface of the connecting member is provided with a conductive film, and each piezoelectric unit comprises two or more piezoelectric crystals stacked in the normal direction, wherein two surfaces of two adjacent piezoelectric crystals adjacent to each other have the same polarity.

17. The piezoelectric acceleration sensor according to claim 16, further comprising:
a plurality of electrode plates, the plurality of electrode plates and the piezoelectric crystals of respective layers are alternately stacked in the normal direction, and the number of layers of the plurality of electrode plates is one more than the number of layers of the piezoelectric crystals, wherein each electrode plate comprises a fitting portion and a connecting portion, the fitting portion is disposed corresponding to the piezoelectric crystal, and the connecting portion is electrically connected to the fitting portion so that each electrode plate is formed as an annular member that is discontinuous in a circumferential direction; and
wherein the respective electrode plates of odd-numbered layers are electrically connected by a wire segment, and the respective electrode plates of even-numbered layers are electrically connected by another wire segment, so that the respective piezoelectric crystals of the at least two piezoelectric units are connected in parallel.

18. The piezoelectric acceleration sensor according to claim 17, wherein the fitting portion has a size greater than or equal to that of the piezoelectric crystal, so that the piezoelectric crystal can completely fit to the fitting portion.

19. The piezoelectric acceleration sensor according to claim 17, wherein the connecting portion has a width in an axial direction of the connecting member smaller than that of the fitting portion.

20. The piezoelectric acceleration sensor according to claim 17, wherein the wire segment electrically connects the electrode plates of the respective odd-numbered layers in the circumferential direction at discontinuous positions of the electrode plates; and the another wire segment electrically connects the electrode plates of the respective even-numbered layers in the circumferential direction at discontinuous positions of the electrode plates.
